(19) United States
(12) Patent Application Publication
(10) Pub. No.: US 2005/0007500 A1
(43) Pub. Date: Jan. 13, 2005

(54) Liquid crystal display with changeable modules

(76) Inventors: Yet-Zen Lin, Taipei (TW); Jin-Wen Liao, Taipei (TW)

Correspondence Address: GREENBERG TRAURIG LLP, 2450 COLORADO AVENUE, SUITE 400E, SANTA MONICA, CA, 90404, US

(21) Appl. No.: 10/813,348

(22) Filed: Mar. 29, 2004

Related U.S. Application Data
(60) Provisional application No. 60/458,256, filed on Mar. 28, 2003.

(30) Foreign Application Priority Data
Sep. 9, 2003 (TW) 092216294

(51) Int. Cl. H05K 7/00

(52) U.S. Cl. 348/790; 348/554

(57) ABSTRACT

An LCD for use in a particular region comprises an electronics board within a housing of the LCD, at least one access slot to the electronics board from outside of the housing; and an at least one insertable module which mates with the electronics board through the at least one access slot, wherein the at least one insertable module is configured for a particular region and comprises at least one of a tuner, an extended audio and video connector, and a power supply.

### CROSS-REFERENCE TO RELATED APPLICATIONS

The contents of this application are related to U.S. Provisional Application No. 60/458,256 (filed Mar. 28, 2003) and to Taiwan Application No. 092216294 (filed Sep. 9, 2003), the contents of which are incorporated herein by reference in their entirety.

### BACKGROUND

1. Field of the Invention

This invention relates to flat displays, more particularly to flat panel liquid crystal displays (LCD's) with a removable and changeable tuner, power and/or audio-video (i.e., A/V) modules which may be located in a separate bay.

2. Description of the Background Art

Because of their compact size and light weight combined with high quality video and/or television output, LCD's have become well known and their use widespread throughout the world. An LCD, designed for use in a specific geographical region, typically includes a tuner customized for the geographical region for receiving audio and video communications wirelessly, a power supply designed for that specific geographical region to deliver the appropriate current and voltage combination for operating the LCD, an audio/video module for interfacing the audio and video signals from an external source (such as a computer) to the LCD. These three components are generally hardwired on a single motherboard, having additional circuitry, in order to deliver the incoming audio and video signals to the loudspeakers and the LCD screen respectively.

As is well known, the LCD can be used as a monitor of computer or a screen of TV. A block diagram of the circuit board of LCD is shown in FIG. 1. The circuit board comprises a tuner 110, a sound processor 120, an AV (audio video) decoder 130, a VGA (Video Graphics Array) connector 140, an ADC (analog-to-digital converter) or receiver 150, a scaler 160, an LCD panel 170, a speaker 180, and a power supply 190.

The AV decoder 130 is used to receive analog or digital RGB (red, green, and blue) signals from a computer (not shown). In a case of analog RGB signals inputted, the signals are converted into digital RGB signals by the ADC 150. In another case of digital RGB signals inputted, the signals are converted into RGB signals having a digital level by the receiver 150. The RGB signals having a digital level are reconverted into video signals by the scaler 160. The video signals are sent to the LCD panel 170 for activation so that images can be shown on the LCD panel 170. The tuner 110 is used to receive TV signals and transmit a video portion of the TV signals to the AV decoder 130. The AV decoder 130 is used to process the video portion of the TV signals for generating digital signals which are in turn converted into video signals by the scaler 160. The video signals are sent to the LCD panel 170 for activation so that images can be shown on the LCD panel 170. As to an audio portion of the TV signals, it is sent to the sound processor 120 to process for generating electric current of sound. The electric current is then sent to the speaker 180 for generating amplified sound. As to the power supply 190, it is used to supply required power to all of the above components and other associated ones of LCD.

However, the tuner specifications for the LCD, which is capable of television reception, vary from geographic region or country. For example, it is known that a display system may belong to one of NTSC, PAL, and SECAM standard. Also, a tuner in the NTSC system will be different from that in the SECAM system. Current methods of manufacturing an LCD include a motherboard having the region specific tuner hardwired thereon.

Furthermore, very specific A/V connections, for use with a flat LC display, are required in various geographic regions and/or countries. Current methods of manufacturing an LCD utilize a motherboard with a region/country specific A/V connections hardwired thereon.

Furthermore, the power supply specifications for the LCD vary from geographic region or country. For example, many European and Asian nations use a 230V/50 Hz power supply while other nations (such as the USA) use 110V/60 Hz power supply. Current methods of manufacturing an LCD include a motherboard having a region specific power supply interface module hardwired thereon.

A major disadvantage of this hardwired design is that it is difficult for a consumer to operate an LCD in a first region when the LCD was purchased in a second region. Another disadvantage is that, it becomes extremely tedious and cost prohibitive for manufacturers to redesign motherboards for every geographical region due to the above types of differences.

### SUMMARY OF THE INVENTION

Since region specific changes in the design of an LCD involve only changes to devices such as the tuner, the power supply and the A/V interface, and not to the motherboard, it is desirable to modularize these devices, to ensure reduced cost and complexity to the manufacturer and the adaptability of the LCD to be used, by the consumer, in various regions with differing transmission, power supply, and connectivity standards.

Accordingly, in one exemplary implementation the LCD uses a single motherboard and can support television reception in a region or country with a specific tuner requirement by using a changeable (viz., insertable) tuner module, wherein the removable tuner module is designed for that specific region.

Accordingly, in another exemplary implementation the LCD uses a single motherboard and can support insertable/removable/changeable A/V input-output connections/connectors (e.g., of “110” type) configured for use with a specific A/V requirement by using a changeable or removable (viz., extended) A/V input-output interface module.

Accordingly, in yet another exemplary implementation LCD uses a single motherboard and can support a insertable/removable/changeable power supply interface module designed for a region or country with a specific power requirement by using a changeable or removable power supply interface module, wherein the removable power supply interface module is designed for that specific region.

Accordingly, in yet another exemplary implementation, the extended audio-video connector module is configured for use with at least one of an S-video input, a component video input, a composite video input, an optical audio input, a coaxial audio input, and an RCA audio input.

In another exemplary implementation a circuit board assembly of an LCD comprising a mother board and a plurality of separate daughter boards wherein the mother board is adapted to assemble with the daughter boards for making the mother board as a circuit board of the LCD.

One exemplary implementation ,provides a circuit board assembly of an LCD, comprising a mother board including an A/V decoder, a VGA connector for receiving analog RGB signals from a computer, an analog-digital converter (i.e., an ADC) for converting the analog RGB signals into digital RGB signals, a scaler for reconverting the digital RGB signals into video signals, and an LCD panel for receiving the video signals from the scaler for activation and showing images thereon in response to the activation; a power supply daughter board (viz., a detachable/insertable/changeable power supply interface module) for supplying a region specific voltage to the mother board; an extended/detachable/insertable/changeable audio-video input-output daughter board comprising a plurality of different audio-video input-output connectors for receiving audio-video signals from the mother board or transmitting the same to the mother board; a tuner daughter board (viz., a detachable/insertable/changeable tuner module) for receiving TV signals and transmitting the same to the AV decoder wherein the tuner module is configured for operation in a specific region.

The A/V decoder is operative to process the TV signals for generating digital signals, and the digital signals are converted into video signals by the scaler. Thus, the removable tuner daughter board, the extended AV I/O daughter board, and the removable power supply module are connected to the mother board for making the mother board as a circuit board of the LCD TV.

In another exemplary implementation an LCD for use in a particular region comprises, (i) an electronics board within a housing of the LCD, (ii) at least one access slot to the electronics board from the outside of the housing, and (iii) an at least one module which mates with the electronics board through the at least one slot, and wherein the at least one module is at least one of a tuner, an A/V connector and a power supply and wherein the at least one tuner, the A/V connector, and the power supply are designed for the particular region. An example of a region is one that employs at least one of a PAL or SECAM or an NTSC system. Another example of a region is one that employs specific power supply standards (e.g., the US region having 110V, 60 Hz or some Asian regions having 230V, 50 Hz).

### BRIEF DESCRIPTION OF THE DRAWINGS

FIG. 1 is a block diagram of a conventional circuit board of an LCD;

FIG. 2 is an exemplary block diagram of an LCD system according to one embodiment;

FIG. 3 is a back view of an LCD according to an exemplary embodiment;

FIG. 4 is a partial view depicting a motherboard and changeable or removable or insertable modules for an LCD system according to an exemplary embodiment;

FIG. 5 is another view depicting a motherboard and changeable or removable or insertable modules for an LCD system according to an exemplary embodiment;

FIG. 6 is an exemplary depiction of a tuner circuit that can be used in the form of an insertable or removable module for the LCD system;

FIG. 7 is an exemplary depiction of a power circuit that can be used in the form of an insertable or removable module for the LCD system;

FIG. 8 is an exemplary depiction of a block diagram of a circuit board with changeable modules for an LCD system according to one embodiment;

It should be appreciated that for simplicity and clarity of illustration, elements shown in the Figures have not necessarily been drawn to scale. For example, the dimensions of some of the elements are exaggerated relative to each other for clarity. Further, where considered appropriate, reference numerals have been repeated among the Figures to indicate corresponding elements.

### DESCRIPTION OF THE EMBODIMENTS

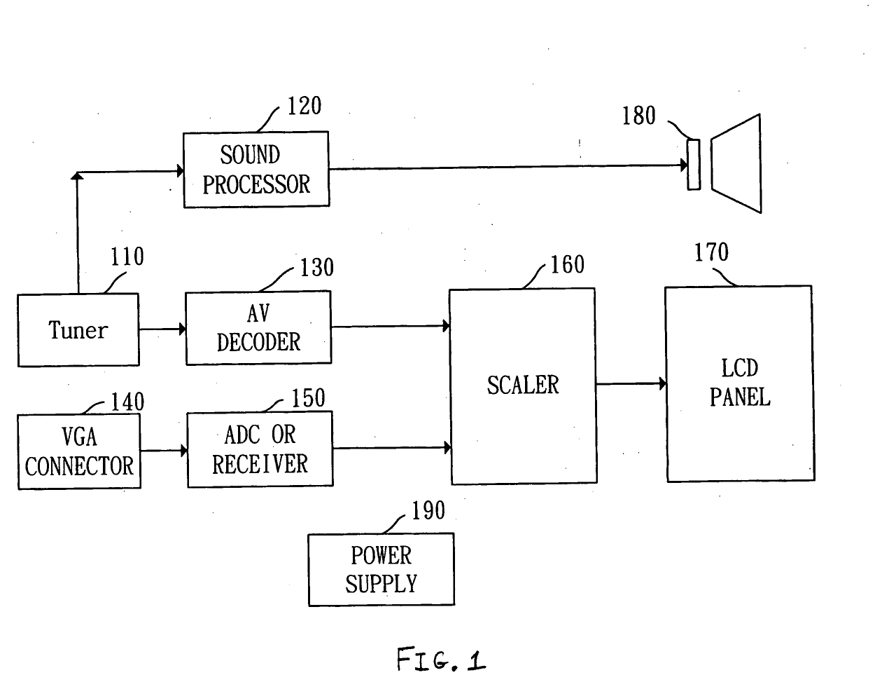

Detailed descriptions are disclosed herein; however, it is to be understood that the disclosed embodiments are merely exemplary of the invention, which may be embodied in various forms. Therefore, specific structural and functional details disclosed herein are not to be interpreted as limiting, but merely as a basis for claims and as a representative basis for teaching one skilled in the art to variously employ the present invention in virtually any appropriately detailed structure. Reference will now be made in detail to that disclosure which is illustrated in the accompanying drawing (FIGS. 1-8).

As is well know, an LCD can be used as a monitor for a computer system, a display for video game console systems, or a screen of a TV. A block diagram of the circuit board of an LCD system is shown in FIG. 1. The circuit board comprises a tuner 110, a sound processor 120, an audio-video (A/V) decoder 130, a Video Graphics Array (VGA) connector 140, an analog-to-digital converter (ADC) or receiver 150, a scaler 160, an LCD panel 170, a speaker 180, and a power supply 190.

The analog to digital converter or receiver 150 is designed to receive signals from a computer or a video game system (not shown). In the case where analog RGB signals are inputted, these signals are converted into digital RGB signals by the ADC 150. In the case where digital signals are inputted, these signals are converted into RGB signals having a digital level set by the receiver 150. The RGB signals having a digital level are reconverted into video signals by the scaler 160. The video signals are then sent to the LCD panel 170 so that images can be shown on the LCD panel 170.

The tuner 110 is used for receiving TV signals and subsequently transmit a video portion of the TV signals to the A/V decoder 130. The A/V decoder 130 is used to process the video portion of the TV signals for generating digital signals which are in turn converted into video signals by the scaler 160. The video signals are sent to the LCD panel 170 so that images can be shown on the LCD panel 170. The audio portion of the TV signal is sent to the sound processor 120 for amplification and other post-processing operations (e.g., virtual surround sound generation) and subsequently to the speaker 180.

The power supply 190 is used to supply required power to all of the above components of the LCD system.

However, the tuner specifications for the LCD, which is capable of television reception, vary from geographic region or country. For example, it is known that a display system may belong to one of NTSC, PAL, and SECAM standard. Also, a tuner in the NTSC system will be different from that in the SECAM system. Thus, the prior art embodiment of FIG. 1 shows an LCD system that includes a motherboard having the region specific tuner hardwired thereon.

Furthermore, very specific A/V connections, for use with a flat LC display, are required in various geographic regions and/or countries. The prior art embodiment of FIG. 1 will also utilize a motherboard with a region/country specific A/V connections hardwired thereon.

Furthermore, the power supply specifications for the LCD vary from geographic region or country. For example, many European and Asian nations use a 230V/50 Hz power supply while other nations (such as the USA) use 110V/60 Hz power supply. The prior art embodiment of FIG. 1 will also include a motherboard having a region specific power supply interface module hardwired thereon.

A major disadvantage of this hardwired design is that it is difficult for a consumer to operate an LCD in a first region when the LCD was purchased in a second region. Another disadvantage is that, it becomes extremely tedious and cost prohibitive for manufacturers to redesign motherboards for every geographical region due to differences in (i) transmission standards (PAL/SECAM/NTSC), (ii) connectivity standards, and (iii) power supply standards.

Thus, one embodiment of the present system is directed to a motherboard of an LCD that can receive changeable tuner modules, changeable power supplies and/or changeable A/V connectors. This manufacturing method eliminates the need for production of multiple motherboards for use in different regions/countries. This method and system can thus allow for configuring a display, for regions/country specific use, after production, thus simplifying the manufacturing process and the device.

Access to the motherboard for changing the tuner module and for A/V connections may be achieved by removing an external shroud of the device, or a bay. The bay may be open or covered. In any event a single motherboard is used for displays to be used in different regions/countries.

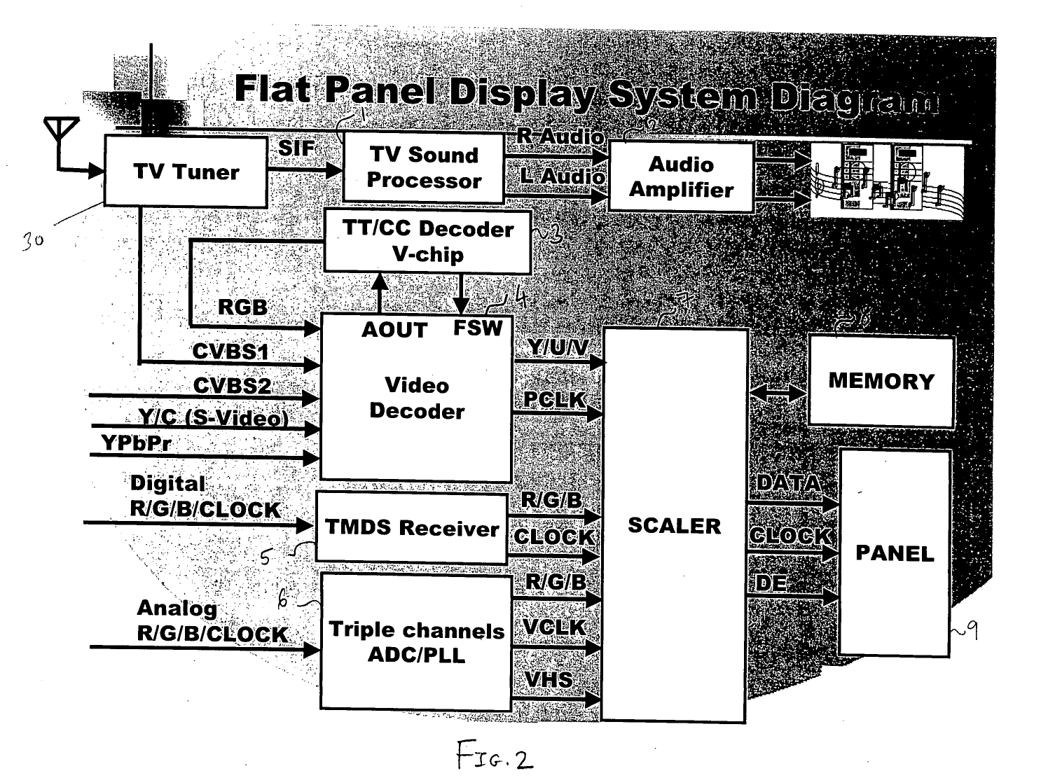

FIG. 2 is an exemplary block diagram of an LCD system according to one embodiment of the present system. Specifically, shown therein, is a changeable tuner 30, that is separate from the motherboard of the LCD system, and is present as an insertable module and connectable to the motherboard of the LCD. The tuner module 30 extracts the audio portion of the TV signal and delivers said audio signal to the sound processor 1 in the LCD or external to the LCD. The sound processor 1 may include algorithms that do virtual surround sound (e.g., Dolby Prologic™, SRS, etc.) and the output of the sound processor 1 is delivered to the audio amplifier 2 for amplification purposes. The output from the amplifier 2 is then supplied speakers located in the LCD or external to the LCD.

The video portion of the TV signal is delivered by the tuner 30 to the video decoder 4 residing on the motherboard. In addition, the decoder 4 accepts inputs from external sources (e.g., computer, video game consoles) via a insertable/changeable A/V connector interface module (not shown in this figure), that is separate from the motherboard. This connector interface module permits an S-video, component video or composite video input. In addition the insertable A/V connector interface module includes connectors such as optical, coaxial, and RCA for audio signals.

The video decoder also receives input from the V-chip 3 resident on the motherboard. The V-chip 3, as is well known in the art, is used for displaying parental controlled programs.

Resident on the motherboard, are the TMDS receiver 5 and the triple channel analog-to-digital controller (ADC) with phase locked loop (PLL) 6. The functionality of these blocks is similar to the functionality of block 150 in FIG. 1.

The outputs from the TMDS receiver 5 and the triple channel analog-to-digital controller (ADC) with phase locked loop (PLL) 6 are delivered to the scaler 7, resident on the motherboard, whose function is similar to the scaler 160 of FIG. 1. A buffer 8 is also resident on the motherboard for storing video information. Finally, the output from the scaler 7 is sent to the display panel 9 of the LCD system for viewing.

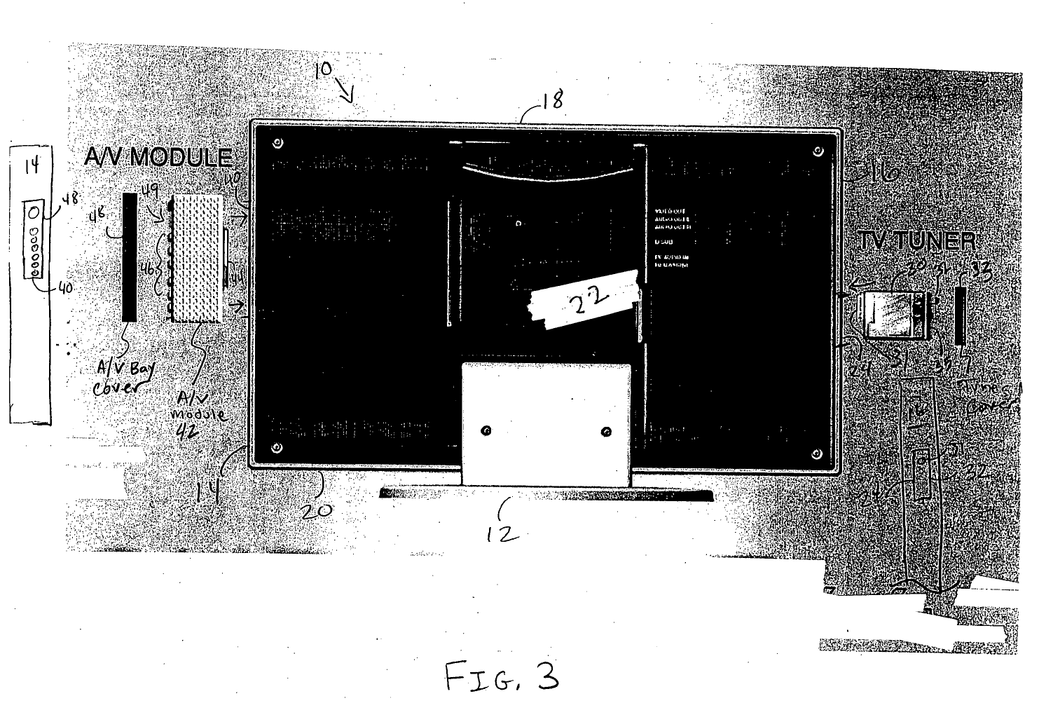

An exemplary embodiment of a back view of the LCD system 10, with changeable modules, is shown in FIG. 3. The LCD system 10 includes a casing 22, supported on a stand 12. The LCD 10 has a two sides 14 and 16, a top 1,8 and a bottom 20.

A tuner access slot 24 in the side 16 of the LCD 10 provides access from the outside of the LCD 10 to an internal area. The tuner module 30, which is separate and external to the motherboard and which provides for television reception in accordance with pre-selected country, or region specific specifications, mates through the tuner access slot 24 into a motherboard (not shown in this figure). The tuner module 30 also may include a tuner plug in jack 31 to mate with the motherboard. The tuner module may further include an input jack 32 which is accessible from the outside of the flat LC display 10. A tuner cover 33 may be fitted over the end of the tuner 35 and tuner access slot 24.

An A/V access slot 40 in the side 14 of the LCD 10 provides access from the outside of the LCD 10 to an internal area. The A/V module 42, which is separate and external to the motherboard and which provides for A/V input/output in accordance with pre-selected country, or region specific specifications, mates through the A/V access slot 40 into a motherboard (not shown in this figure). The A/V module 42 has an A/V plug in jack 44 to mate with the motherboard. The A/V module has input/output jacks 46 (e.g., component video, composite video, S-video, coaxial audio, optical audio, RCA audio) which are accessible from the outside of the LCD 10. An A/V cover 48 can be fitted over the end of the A/V module 49 and A/V access slot 40.

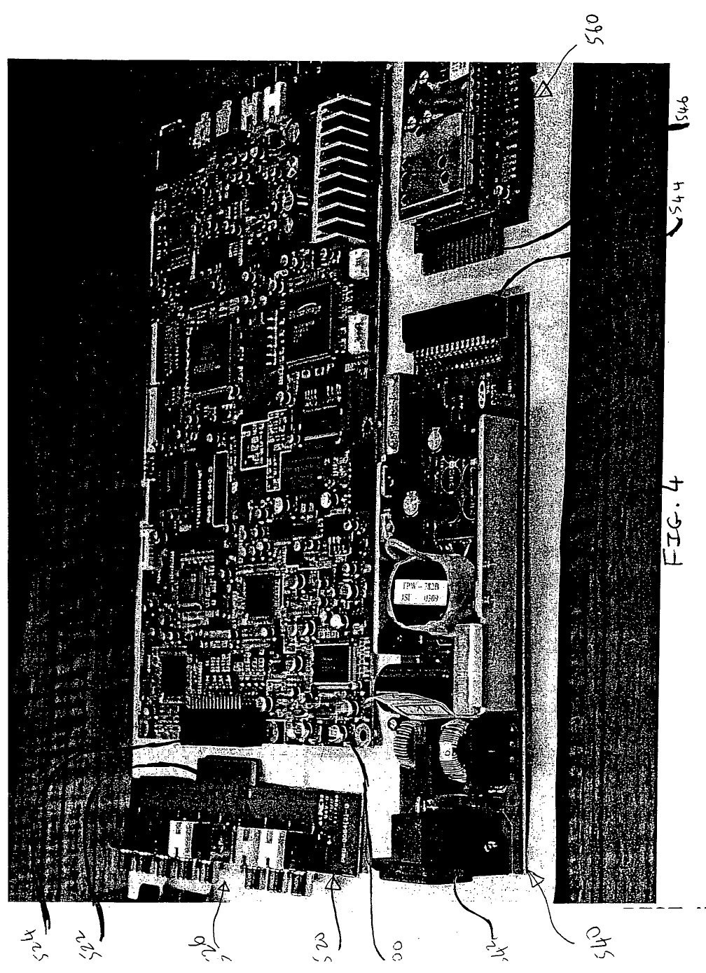

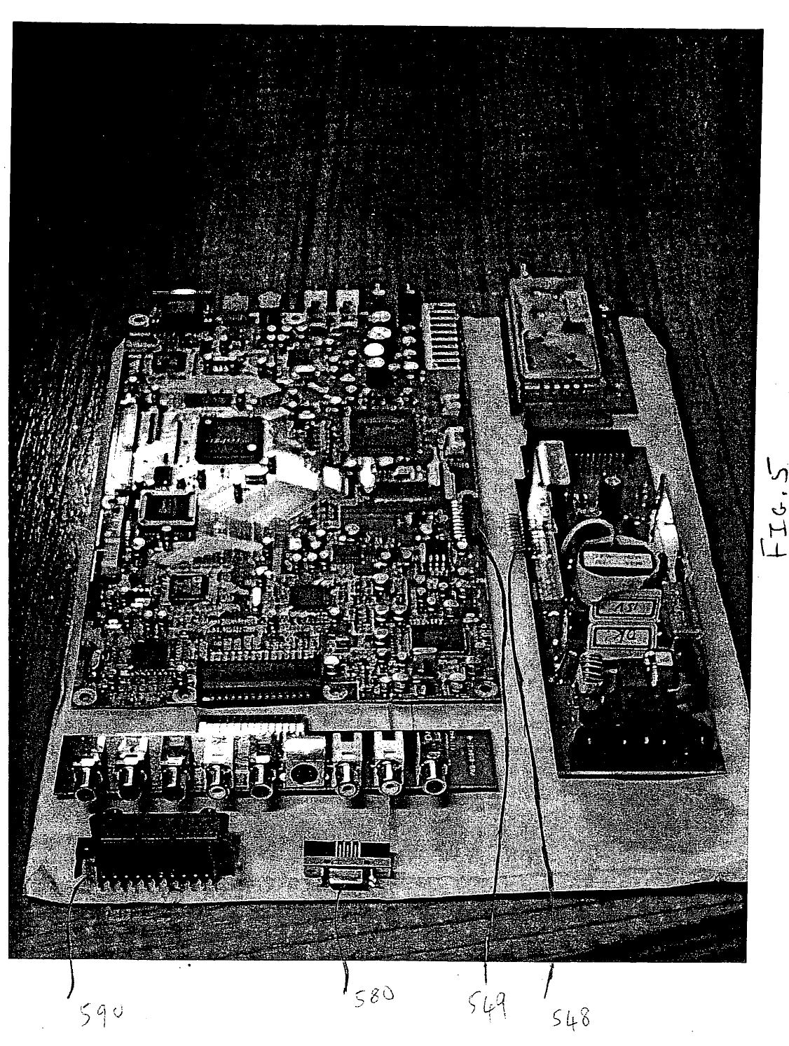

FIGS. 4 and 5 are views depicting a motherboard with changeable or removable or insertable tuner, connector, and power modules for an LCD system according to an exemplary embodiment. Specifically, shown therein is a motherboard 500 that is included within the casing of the LCD system and which provides the major electronic components to operate an LCD panel connected thereto, and is also configured to accept one or more plug-in modules (viz., tuner module 560, power supply module 540, and an A/V connector module 520). In this fashion a single motherboard 500 can be configured after production for use in different countries by utilizing changeable tuner module 560, changeable power supply module 540, and changeable A/V connector module 520. The power delivery from the power supply module 540 to the tuner module 560 is achieved by establishing connection between two connectors (viz., a female connector 544 in the power supply module 540 and a male connector 546 in the tuner module 560).

Similarly, the power delivery from the power supply module 540 to the motherboard 500 is achieved by establishing connection between two connectors (viz., a male connector 548 in the power supply module 540 and a female connector 549 in the motherboard 500). An input connector 542 on the power supply module 540 allows a user to connect a power supply (not shown) to the changeable power supply module 540 and in effect power the motherboard 500 and changeable tuner module 560. The changeable A/V connector module 520 includes different types of connectors such as VGA 580, SCART type 590, S-video, component video, composite video, coaxial audio, optical audio, and RCA audio (shown generally by 526). The removable or changeable module 520 has a male type of a connector 522 which mates with a female connector 524 on the motherboard 500 to allow various input/out connectivity with the motherboard 500.

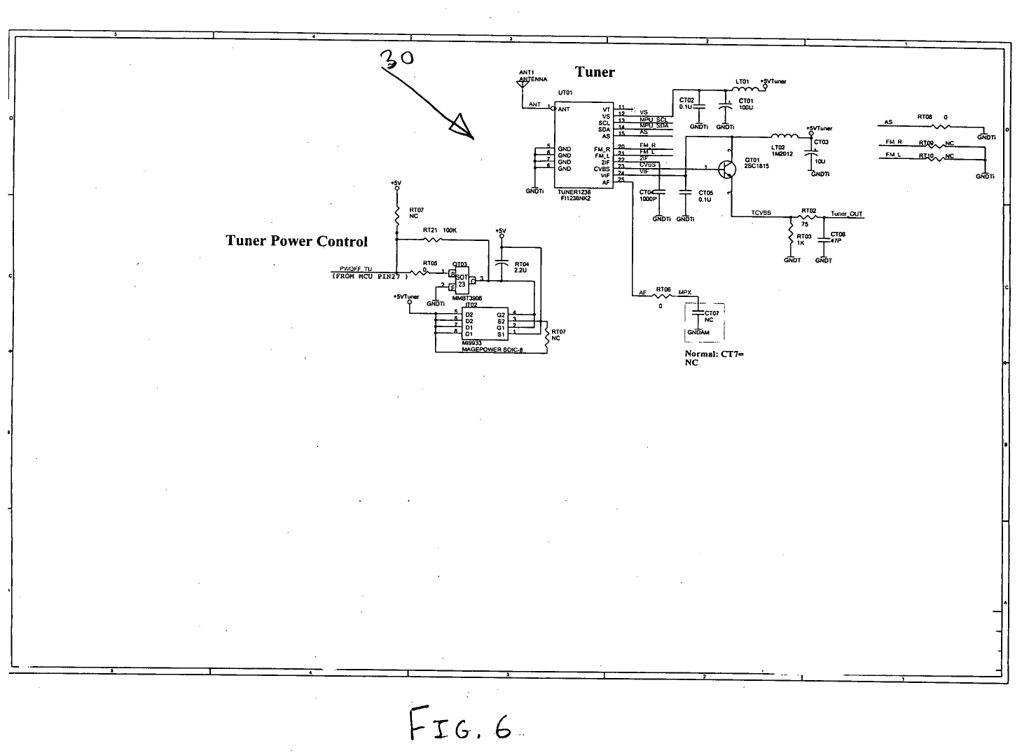

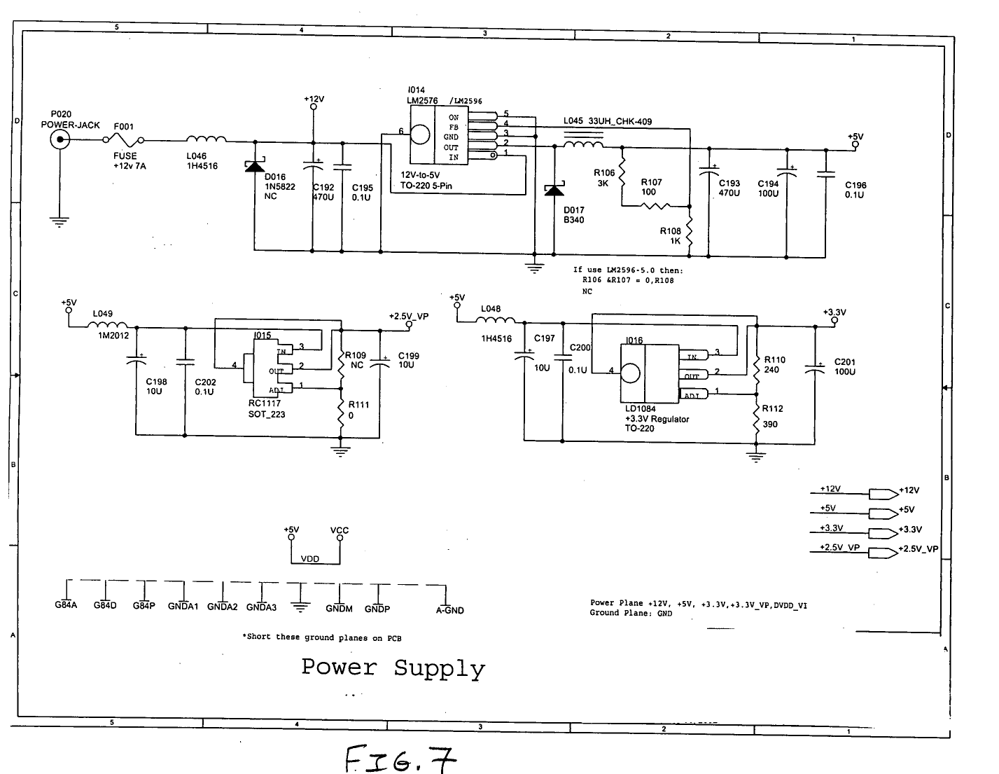

FIGS. 6 and 7 give an exemplary depiction of a tuner circuit and a power supply circuit that can be used in the form of an insertable or removable tuner modules and power supply modules, respectively, for the LCD system. Examples of tuner IC chips that can be used in the tuner module is the Phillips FL1236N or the FQ1236 which provides channel coverage in 3 bands: (i) Low band (between 55.25 and 16 MHz), (ii) Mid band (between 160 and 442 MHz), and (iii) High band (between 442 and 801.25 MHz).

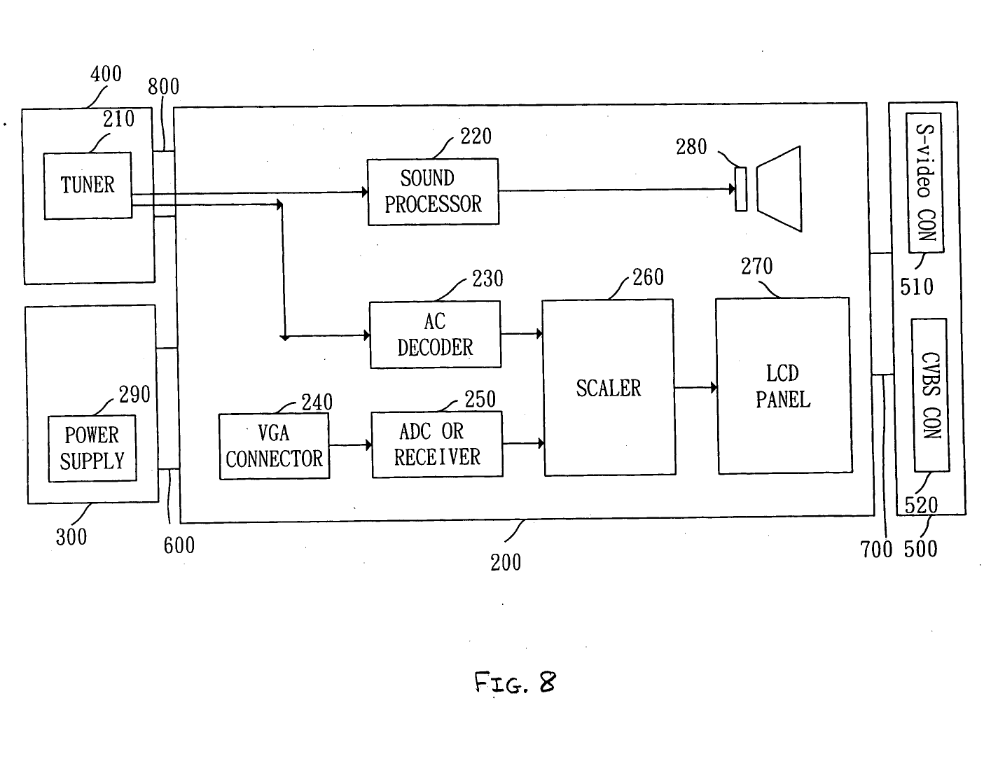

FIG. 8 is an exemplary depiction of a block diagram of a circuit board with changeable modules for an LCD system according to another embodiment.

With reference to FIG. 8, shown therein is a circuit board assembly of an LCD system constructed in accordance with the invention comprising a mother board 200, a power supply daughter board 300, a tuner daughter board 400, and an extended AV I/O (input/output) daughter board 500.

The mother board 200 comprises a sound processor 220, an A/V decoder 230, a VGA connector 240, an ADC or receiver 250, a scaler 260, an LCD panel 270, and a speaker 280. The mother board 200 is used to receive analog RGB signals from a computer via the VGA connector 240. The RGB signals are then converted into digital RGB signals by the ADC or receiver 250. The digital RGB signals are then reconverted into video signals by the scaler 260. Next, the video signals are sent to the LCD panel 270 so that images can be shown on the LCD panel 270.

The power supply daughter board 300 comprises a power supply 290 for supplying different voltages to all of the above components of the mother board 200. A first connecting member 600 is electrically interconnected the power supply daughter board 300 and the mother board 200. The tuner daughter board 400 comprises a tuner 210 for receiving TV signals and transmitting the same to the AV decoder 230. The AV decoder 230 is used to process the TV signals for generating digital signals which are in turn converted into video signals by the scaler 260. The video signals are sent to the LCD panel 270 so that images can be shown on the LCD panel 270. A second connecting member 800 electrically interconnects the tuner daughter board 400 with the mother board 200.

The extended AV I/O daughter board 500 comprises a number of AV I/O connectors including a S-video connector 510, a CVBS connector 520, and connectors of other types (as was explained in reference to FIGS. 4 and 5). The extended A/V I/O daughter board 500 is used to receive A/V signals from the mother board 200 or transmit the same to the mother board 200 in response to connecting the extended A/V I/O daughter board 500 to the mother board 200. A third connecting member 700 electrically interconnects the extended AV I/O daughter board 500 with the mother board 200.

Thus, the power supply daughter board 300, the extended AV I/O daughter board 500, and the tuner daughter board 400 are electrically connected to the mother board 200 via the connecting members 600, 700, and 800 respectively. Each of the connecting members 600, 700, and 800 is implemented as a pair of mated connectors, a slot and a connector adapted to insert into the slot, or a bus and two end connectors. The circuit board of LCD can be formed by connecting the power supply daughter board 300 to the mother board 200. In use, a user may connect one or more of the power supply daughter board 300, the extended AV I/O daughter board 500, and the tuner daughter board 400 to the mother board 200 via one of more of the connecting members 600, 700, and 800 respectively depending on TV systems, screen sizes, etc. For example, a user may connect the tuner daughter board 400 and the extended AV I/O daughter board 500 to the mother board 200 for making the mother board 200 as a circuit board of TV.

It is to be understood that other embodiments may be utilized and structural and functional changes may be made without departing from the respective scope of the present invention. Possible modifications to the system include, but are not limited to, design of different mating connections between the tuner module, the power supply module, the A/V connector module with the motherboard. Also, the LCD panel may be modular in that different types of panels having different features/quality may be removed and added to the LCD system as needed.

1. An LCD for use in a particular region comprising:
an electronics board within a housing of the LCD;
at least one access slot to the electronics board from outside of the housing; and
an at least one insertable module which mates with the electronics board through the at least one access slot;
wherein the at least one insertable module is configured for a particular region and comprises at least one of a tuner, an extended audio and video connector, and a power supply.

2. The LCD according to claim 1 wherein the tuner module is configured for use in a region having a PAL video standard.

3. The LCD according to claim 1 wherein the tuner module is configured for use in a region having a SECAM video standard.

4. The LCD according to claim 1 wherein the tuner module is configured for use in a region having an NTSC video standard.

5. The LCD according to claim 1 wherein the power supply module is configured for use in a region having a 230 V AC and 50 Hz power transmission standard.

6. The LCD according to claim 1 wherein the power supply module is configured for use in a-region having a 110 V AC and 60 Hz power transmission standard.

7. The LCD according to claim 1 wherein the extended audio-video connector module is configured for use with at least one of an S-video input, a VGA input, a SCART input, a component video input, a composite video input, an optical audio input, a coaxial audio input, and an RCA audio input.

8. A circuit board assembly of an LCD, comprising:
a mother board including (i) an audio-video decoder, (ii) a connector interface for receiving at least one analog signal from an external source, (iii) an analog to digital converter for converting the at least one analog signal into an at least one digital signal, (iv) a scaler for reconverting the at least one digital signal into an at least one video signal, and (v) an LCD panel for receiving the at least one video signal from the scaler for displaying images thereon;
an insertable power supply module for generating power to operate the motherboard, said power supply module being configured to operate at a power supply rating specific to a region where the LCD is to be operated;
an insertable audio-video interface module comprising audio-video input-output connectors for receiving audio-video signals from the mother board or transmitting the same to the mother board; and
an insertable tuner module for receiving the TV signal and transmitting the same to the audio-video decoder, wherein the tuner module is configured for operation in the region.

9. The circuit board assembly of claim 8 wherein the external source is a computer.

10. The circuit board assembly of claim 8 wherein the external source is a video game console system.
